(19) United States
(12) Patent Application Publication
(10) Pub. No.: US 2026/0367315 A1
(43) Pub. Date: Nov. 19, 2026

(54) PART OF A PHOTONIC INTEGRATED CIRCUIT AND METHOD OF MANUFACTURING SAME

(71) Applicant: SMART PHOTONICS HOLDING B.V., Eindhoven (NL)

(72) Inventors: Alonso Jesús MILLÁN-MEJÍA, Eindhoven (NL); Netsanet Merawi TESSEMA, Eindhoven (NL)

(21) Appl. No.: 19/736,336

(22) Filed: Jul. 9, 2026

Related U.S. Application Data
(63) Continuation of application No. PCT/EP2025/050615, filed on Jan. 10, 2025.

(30) Foreign Application Priority Data
Jan. 12, 2024 (GB) 2400496.2

(51) Int. Cl. G02B 6/122; G02B 6/12; G02B 6/134; G02B 6/136

(52) U.S. Cl. CPC G02B 6/122; G02B 6/134; G02B 6/136; G02B 2006/12123; G02B 2006/12126; G02B 2006/12173; G02B 2006/12176

(57) ABSTRACT

A part of a photonic integrated circuit comprising: a semiconductor waveguide, an electrically conductive n-type semiconductor layer, and a photodiode. The semiconductor waveguide is on a substrate. The electrically conductive n-type semiconductor layer is between the semiconductor waveguide and the substrate. A portion of the electrically conductive n-type semiconductor layer has been removed by etching between the semiconductor waveguide and the substrate. The photodiode is optically connected to the semiconductor waveguide.

### CROSS-REFERENCE TO RELATED APPLICATIONS

This application is a continuation under 35 U.S.C. § 120 of International Application No. PCT/EP2025/050615, filed Jan. 10, 2025, which claims priority to GB Application No. 2400496.2, filed Jan. 12, 2024, under 35 U.S.C. § 119(a). Each of the above-referenced patent applications is incorporated by reference in its entirety.

### BACKGROUND

Electrical current between components and photodiodes of a photonic integrated circuit (PIC) can lead to electrical crosstalk which can reduce the lifetime of components, introduce error in photodetection, and reduce the sensitivity of photodetection. It is desirable to reduce electrical current between components and photodiodes of a PIC.

### BRIEF DESCRIPTION OF THE DRAWINGS

FIG. 1 is a flow diagram of a method of manufacturing a part of a PIC in accordance with examples;

FIG. 2 shows schematically a flow diagram of three views of the part of the PIC during the method of FIG. 1;

FIG. 3 is a flow diagram of a method of forming a semiconductor waveguide in accordance with further examples;

FIG. 4 shows schematically a flow diagram of side cross-sections of the part of the PIC during the method of FIG. 3;

FIG. 5 is a flow diagram of a method of forming a semiconductor waveguide in accordance with further examples;

FIG. 6 shows schematically a flow diagram of side cross-sections of the part of the PIC during the method of FIG. 5;

FIG. 7 is a flow diagram of an additional part of a method of manufacturing a part of a PIC in accordance with further examples;

FIG. 8 shows schematically views of the part of the PIC during the method of FIG. 8;

FIG. 9 is a flow diagram of a method of manufacturing a part of a PIC in accordance with further examples;

FIG. 10 shows schematically a flow diagram of side cross-sections of the part of the PIC during the method of FIG. 9; and

FIG. 11 shows schematically a top plan view and two side cross-sections of a balanced photodetector of a PIC of examples.

### DETAILED DESCRIPTION

In photonic integrated circuits (PICs), components are optically connected to photodiodes by semiconductor waveguides. An electrically conductive n-type semiconductor layer is typically used as a shared electrical earth for photodiodes, semiconductor waveguides and other components of the PIC. To function as a shared electrical earth, the electrically conductive n-type semiconductor layer has a sufficiently high electrical conductivity and connects the components of a PIC and the semiconductor waveguides. The shared electrically conductive n-type semiconductor layer however can cause electrical crosstalk or noise between components and a photodiode of the PIC.

Examples described herein relate to part of a PIC with a reduced electrical connectivity between components of the PIC and a photodiode. The reduction in electrical connectivity reduces electrical current between the components and the photodiode, which in turn reduces electrical crosstalk between the components of the PIC and the photodiode of the PIC. In some examples this increases the lifetime of the PIC and the photodiode; reduces the error induced in the photodiode; allows more sensitive photodetection; allows heterodyne detection; and/or allows more efficient photodetection.

The electrically conductive n-type semiconductor layer and an n-type semiconductor layer of a semiconductor waveguide optically connected to the photodiode are electrical conductors. So, it was found that during use of PICs not of examples herein, undesirable electrical current may flow to or from the photodiode of the PIC through at least one of: the electrically conductive n-type semiconductor layer, or the n-type semiconductor layer of the semiconductor waveguide.

To address these problems, in examples described herein, a portion of the electrically conductive n-type semiconductor layer is etched without etching a portion of the semiconductor waveguide on the portion of the electrically conductive n-type semiconductor layer. The portion of the electrically conductive n-type semiconductor layer that is etched is between the semiconductor waveguide and a substrate. Such etching may be referred to as under-etching. The absence of the portion of the electrically conductive n-type semiconductor between the substrate and the waveguide because of the under-etching was found to reduce electrical current flowing between components of the PIC and the photodiode through the electrically conductive n-type semiconductor layer compared to without the under-etching.

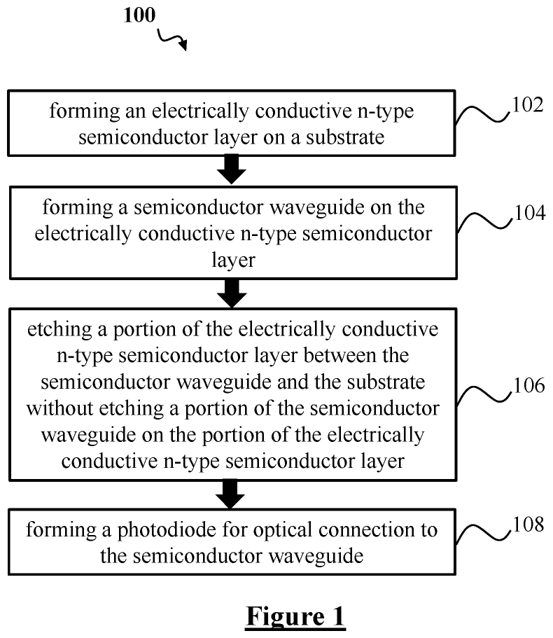

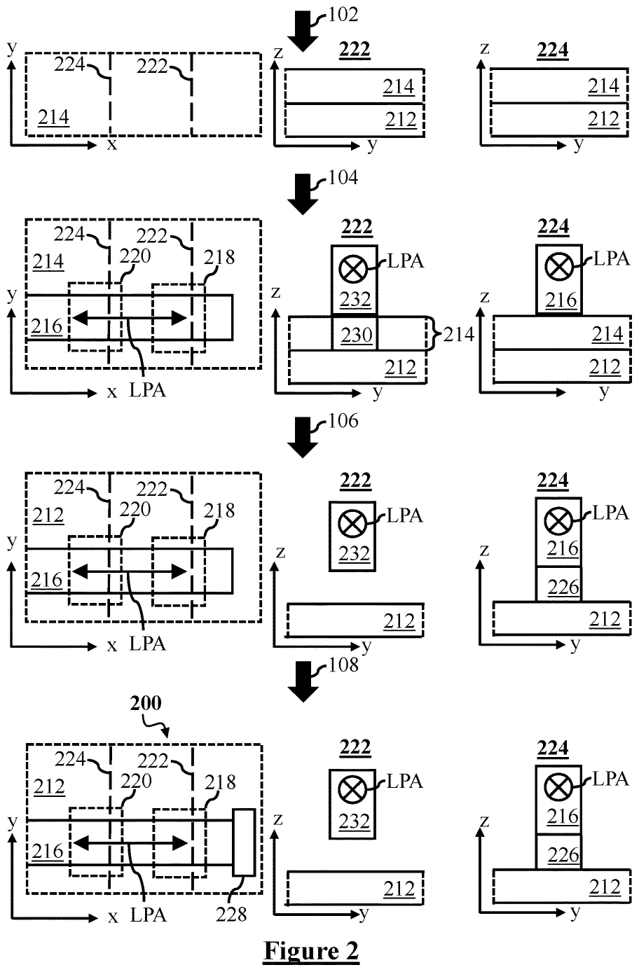

A general introduction to examples herein relating to a method 100 of manufacturing part of a PIC and a part 200 of a PIC is now given with reference to FIGS. 1 and 2. Where a feature in relation to FIG. 2 corresponds with a feature described using FIG. 1, the same reference numeral is used. FIG. 1 is a flow diagram of a method 100 of manufacturing a part 200 of a PIC. FIG. 2 shows schematically three views during the method of FIG. 1. The relative orientations of each view are indicated using cartesian x-, y-, and z-axes. The three views are: a top plan view (xy-plane) and a side cross-section taken on a first plane 222 (yz-plane) and a side cross-section taken on a second plane 224 (yz-plane). The side cross-sections are each labelled with the reference numeral of the plane they are taken on.

The method 100 comprises forming 102 an electrically conductive n-type semiconductor layer 214 on a substrate 212. The electrically conductive n-type semiconductor layer 214 is in contact with the substrate 212. In other examples, the part of the PIC comprises a layer and/or portion between the electrically conductive n-type semiconductor layer and the substrate.

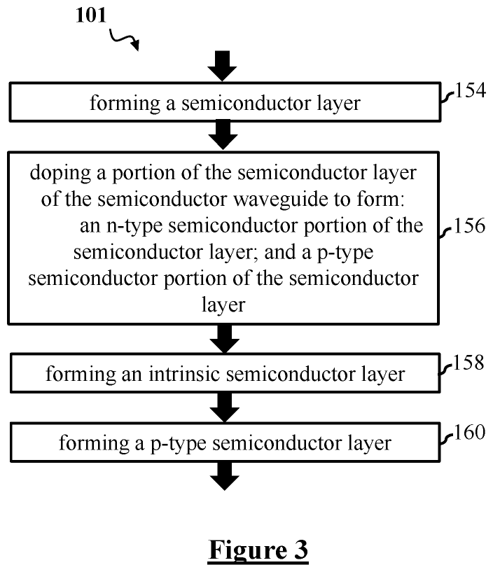

The method 100 then comprises forming 104 a semiconductor waveguide 216 on the electrically conductive n-type semiconductor layer 214. The waveguide 216 is a ridge waveguide. Different morphologies of the waveguide are envisaged for other examples. In some examples, forming the semiconductor waveguide comprises several processes or techniques, e.g.: forming a semiconductor waveguide precursor; forming a lithographic mask; lithography to form the semiconductor waveguide; and removing the lithographic mask. Further example methods of forming the semiconductor waveguide are envisaged, some examples of such are described later with reference to FIGS. 3 to 6.

The method 100 next comprises etching 106 a portion 230 of the electrically conductive n-type semiconductor layer 214 between the semiconductor waveguide 216 and the substrate 212 without etching a portion 232 of the semiconductor waveguide 216 on the portion 230 of the electrically conductive n-type semiconductor layer 214. The semiconductor waveguide 216 is not etched at all. In other examples the semiconductor waveguide is at least partly etched. In some examples the etching of the portion of the electrically conductive n-type semiconductor layer comprises several processes or techniques, e.g.: forming an etch mask on the semiconductor waveguide, etching the portion of the electrically conductive n-type semiconductor layer; and removing the etch mask, other processes and techniques are envisaged, some examples of such are described later in more detail. Both the portion 232 of the semiconductor waveguide 216 and the portion 230 of the electrically conductive n-type semiconductor layer 214 are in a first portion 218 of the part of the PIC and not in a second portion 220 of the part of the PIC. The second portion 220 of the part of the PIC comprises an un-etched portion 226 of the electrically conductive n-type semiconductor layer 214. The first plane 222 is through the first portion 218 and the second plane 224 is through the second portion 220. The un-etched portion of the electrically conductive n-type semiconductor layer 214 is between the substrate 212 and the semiconductor waveguide 216. An electrical conductivity of the first portion 218 of the part of the PIC is less than an electrical conductivity of the second portion 220 of the part of the PIC at least partly because the n-type semiconductor layer 214 is absent from the first portion 218 of the part of the PIC. The first portion 218 of the part of the PIC is an electrically insulating portion of the PIC and the second portion 220 of the part of the PIC is an electrically conductive portion of the PIC.

The method 100 then comprises forming 108 a photodiode 228 for optical connection to the semiconductor waveguide 216. The photodiode 228 is optically connected to the semiconductor waveguide 216. The photodiode 228 is integrated into the PIC. In other examples, the photodiode is at least one of: integrated with the PIC through hybrid integration, on a different PIC, on an integrated circuit (IC), or shares a printed circuit board (PCB) with the semiconductor waveguide.

In some examples, at any point after etching 106 a portion of the electrically conductive n-type semiconductor layer between the semiconductor waveguide and the substrate, a material with an electrical conductivity less than an electrical conductivity of the electrically conductive n-type semiconductor layer is formed. The material is in place of the portion of the electrically conductive n-type semiconductor layer previously etched. The material is between the semiconductor waveguide and the substrate, and in the first portion of the part of the PIC. In some examples, the material is at least one of: a semiconductor, a p-type semiconductor, a polymer, a dielectric, a fluid, air, or a vacuum. Other materials with an electrical conductivity less than an electrical conductivity of the electrically conductive n-type semiconductor layer are envisaged.

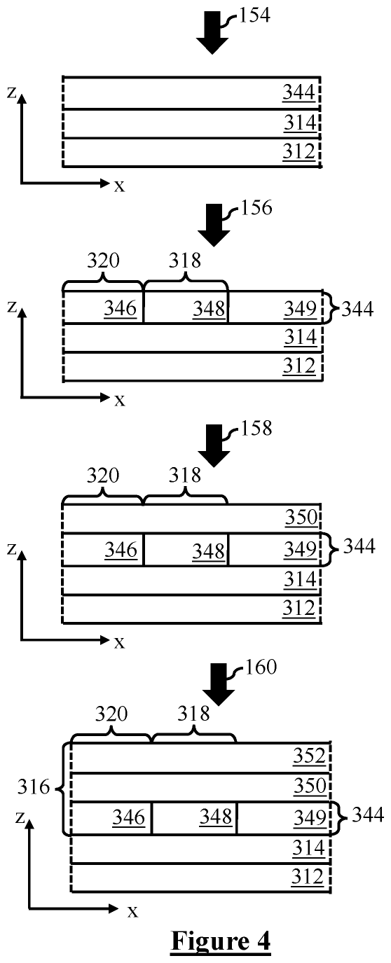

A description of a method 101 of forming a semiconductor waveguide of further examples is now given in relation to FIGS. 3 and 4. The method 101 of forming a semiconductor waveguide is an example of part of the method of manufacturing part of a PIC previously described in relation to FIGS. 1 and 2. The method 101 of forming a semiconductor waveguide 316 of such examples would be preceded at least by forming an electrically conductive n-type semiconductor layer on a substrate as previously described; and would be followed by at least etching a portion of the electrically conductive n-type semiconductor layer, and forming a photodiode as previously described.

FIG. 3 is a flow diagram of an example method 101 of forming a semiconductor waveguide of previously described examples. FIG. 4 shows schematically side cross sections of the part of the PIC during the method of FIG. 3. The relative orientations of each view are indicated using cartesian x-, y-, and z-axes.

Where a feature in relation to FIG. 4 corresponds with a feature described using FIG. 2, a reference numeral is used which is 100 greater than the corresponding reference numeral used for FIG. 2 (e.g., 212 in FIG. 2 is 312 in FIG. 4); corresponding descriptions for such features apply here also. Where a feature in relation to FIG. 4 corresponds with a feature described using FIG. 3, the same reference numeral is used.

Forming a semiconductor waveguide 316 on the electrically conductive n-type semiconductor layer 314 comprises at least the following. Firstly, the method 103 comprises forming 154 a semiconductor layer 344. The semiconductor layer 344 on the electrically conductive n-type semiconductor layer 314. The forming 154 the semiconductor layer 344 comprises epitaxy; other processes and techniques are envisaged for other examples.

The method 103 then comprises doping 156 a portion of the semiconductor layer 344 of the semiconductor waveguide to form an n-type semiconductor portion 346 of the semiconductor layer 344; and a p-type semiconductor portion 348 of the semiconductor layer 344. In some examples a portion of the semiconductor layer is doped with an electron donor to form the n-type semiconductor portion, e.g. iron (Fe). In other examples a portion of the semiconductor layer is doped with an electron hole donor, e.g. zinc (Zn) to form the p-type semiconductor portion. In a further example, a first portion of the semiconductor layer is doped with an electron donor to form the n-type semiconductor portion and a second portion of the semiconductor layer is doped with an electron hole donor to form the p-type semiconductor portion. In some examples doping comprises at least one of diffusion or implantation. An electrical conductivity of the p-type semiconductor portion 348 is less than an electrical conductivity of the n-type semiconductor portion 346. In some examples, such as those of FIG. 3 and FIG. 4, a p-n diode is formed at an interface between the p-type semiconductor portion 348 and the n-type semiconductor portion 346. In some such examples, the p-n diode prevents or reduces the flow of electrons from the p-type semiconductor portion 348 to the n-type semiconductor portion 346, allowing the semiconductor waveguide to have a greater electrical resistance in one direction parallel to the light propagation axis.

In some examples, such as those of FIG. 3 and FIG. 4, the n-type semiconductor portion 346 is a first n-type semiconductor portion 346, and the p-type semiconductor portion 348 is between the first n-type semiconductor portion 346 and a second n-type semiconductor portion 349 in the semiconductor layer. In some such examples, a first p-n diode is formed at an interface between the p-type semiconductor portion 348 and the first n-type semiconductor portion 346; and a second p-n diode is formed at an interface between the p-type semiconductor portion 348 and the second n-type semiconductor portion 349. The first and second p-n diodes each prevents or reduces the flow of electrons from the p-type semiconductor portion to the respective first and second n-type semiconductor portion, allowing the waveguide to have a greater electrical resistance in two opposed directions parallel to the light propagation axis of the semiconductor waveguide 316. Other diodes are envisaged such as a p-i-n diode. In some such examples, the electrical resistance of the semiconductor waveguide can be increased in a small footprint compared to the footprint needed without a p-n diode or a first and second p-n diode.

Then the method 101 comprises forming 158 an intrinsic semiconductor layer 350 on the semiconductor layer 344. The intrinsic semiconductor layer comprises an indium gallium arsenide phosphide (InGaAsP) multi quantum well material. Other intrinsic semiconductor materials and/or configurations are envisaged. The intrinsic semiconductor layer is in contact with the semiconductor layer. In other examples there is a layer between the semiconductor layer and the intrinsic semiconductor layer, e.g. a further semiconductor layer.

Then the method 101 comprises forming 160 a p-type semiconductor layer 352 on the intrinsic semiconductor layer 350. The intrinsic semiconductor layer 350 is between the semiconductor layer 344 and the p-type semiconductor layer 352. The semiconductor layer 344 is between the intrinsic semiconductor layer 350 and the electrically conductive n-type semiconductor layer 314. The intrinsic semiconductor layer is in contact with the p-type semiconductor layer. In other examples there is a layer between the p-type semiconductor layer and the intrinsic semiconductor layer, e.g., a further semiconductor layer.

In such examples, after etching the portion of the electrically conductive n-type semiconductor layer 314 between the semiconductor waveguide 316 and the substrate 312: the electrically conductive n-type semiconductor layer 314 is at least partly absent from between the p-type semiconductor portion 348 and the substrate 312. The p-type semiconductor portion 348 is in the first portion 318 of the part of the PIC. The n-type semiconductor portion 346 is in the second portion 320 of the part of the PIC. An electrical conductivity of the first portion 318 of the part of the PIC is less than an electrical conductivity of the second portion 320 of the part of the PIC at least partly because the n-type semiconductor portion 346 has a greater electrical conductivity than the p-type semiconductor portion 348, and the formation of a p-n diode.

The p-type semiconductor portion 348 is entirely within the first portion 318 of the part of the PIC and the n-type semiconductor portion 346 is entirely within the second portion 320 of part of the PIC. In other examples the p-type semiconductor portion is partly in the first portion 318 of the part of the PIC; and the n-type semiconductor portion 346 is partly in the second portion 320 of the part of the PIC.

The electrical conductivity of the semiconductor waveguide is reduced compared to other semiconductor waveguides. The reduced electrically conductivity of the semiconductor waveguide was found to reduce or prevent electrical current flowing between components of the PIC and the photodiode through the semiconductor waveguide.

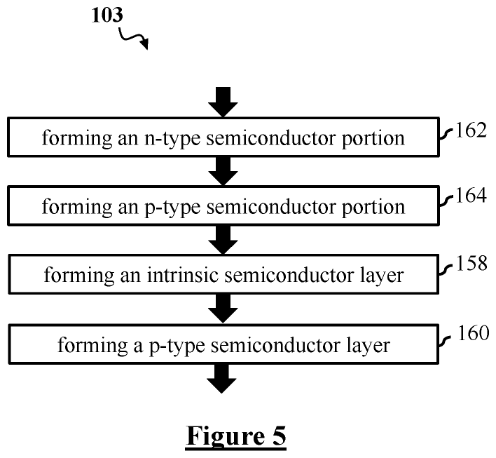

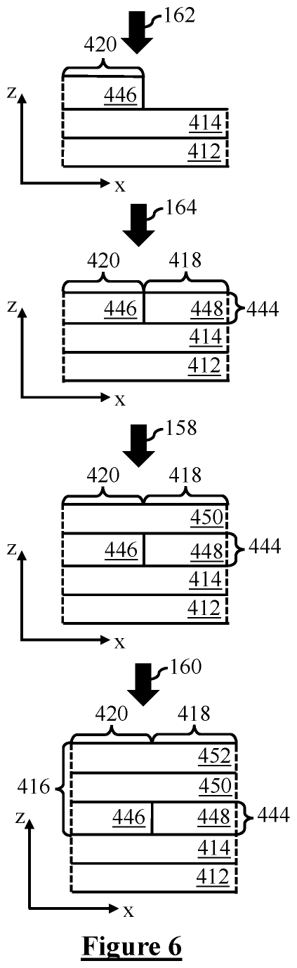

A description of a method 103 of forming a semiconductor waveguide 416 of further examples is now given in relation to FIG. 5 and FIG. 6. The method 103 of forming a semiconductor waveguide is an example of part of the method of manufacturing part of a PIC previously described in relation to FIG. 1 and FIG. 2. In such examples the method 103 of forming a semiconductor waveguide 416 would be proceeded at least by forming an electrically conductive n-type semiconductor layer on a substrate as previously described; and would be followed by at least etching a portion of the electrically conductive n-type semiconductor layer, and forming a photodiode as previously described.

FIG. 5 is a flow diagram of a method 103 of forming a semiconductor waveguide 416 of further examples. FIG. 6 schematically shows side cross-sections of the part of the PIC during the method 103 of FIG. 5. The relative orientations of each view are indicated using cartesian x-, y-, and z-axes.

Where a feature in relation to FIG. 5 corresponds with a feature described using FIG. 3, the same reference numeral is used. Where a feature in relation to FIG. 6 corresponds with a feature described using FIG. 4 a reference numeral is used which is 100 greater than the corresponding reference numeral used for FIG. 6 (e.g., 412 in FIG. 6 is 312 in FIG. 4); corresponding descriptions for such features apply here also.

In the examples of FIG. 5 and FIG. 6, forming a semiconductor waveguide 416 on the electrically conductive n-type semiconductor layer 414 comprises at least the following.

Similarly to method 101 of FIG. 3 and FIG. 4, the method 103 of FIG. 5 and FIG. 6 firstly comprises forming a semiconductor layer 444. The semiconductor layer 444 on the electrically conductive n-type semiconductor layer 414. In contrast to the method 101 of FIG. 3 and FIG. 4, the method 103 of FIG. 5 and FIG. 6 then comprises: forming 162 an n-type semiconductor portion 446; and forming 164 a p-type semiconductor portion 448. The n-type semiconductor portion 446 and the p-type semiconductor portion 448 are on the electrically conductive semiconductive layer 414. In the examples of FIGS. 5 and 6 the n-type semiconductor portion 446 is formed before the p-type semiconductor portion 448 is formed. In other examples, the p-type semiconductor portion 448 is formed before the n-type semiconductor portion 446 is formed. Similarly to the method 101 of FIGS. 3 and 4: an electrical conductivity of the p-type semiconductor portion 448 is less than an electrical conductivity of the n-type semiconductor portion 446.

A p-n diode is formed at an interface between the p-type semiconductor portion 448 and the n-type semiconductor portion 446. In some such examples, the p-n diode prevents or reduces the flow of electrons from the p-type semiconductor portion 448 to the n-type semiconductor portion 446, allowing the semiconductor waveguide to have a greater electrical resistance in one direction parallel to the light propagation axis.

In some examples, the p-type semiconductor portion is between a first n-type semiconductor portion and a second n-type semiconductor portion in the semiconductor layer. In such examples a first p-n diode is formed at an interface between the p-type semiconductor portion and the first n-type semiconductor portion; and a second p-n diode is formed at an interface between the p-type semiconductor portion and the second n-type semiconductor portion. The first and second p-n diodes each prevents or reduces the flow of electrons from the p-type semiconductor portion to the respective first and second n-type semiconductor portion, allowing the semiconductor waveguide to have a greater electrical resistance in two opposed directions parallel to the light propagation axis of the semiconductor waveguide.

The method part 103 then comprises forming 158 an intrinsic semiconductor layer 450 on the semiconductor layer 444. Then the method 103 comprises forming 160 a p-type semiconductor layer 452 on the intrinsic semiconductor layer 450. The intrinsic semiconductor layer 450 is between the semiconductor layer 444 and the p-type semiconductor layer 452. The semiconductor layer 444 is between the intrinsic semiconductor layer 340 and the electrically conductive n-type semiconductor layer 414.

In such examples, after etching the portion of the electrically conductive n-type semiconductor layer 414 between the semiconductor waveguide 416 and the substrate 412: the electrically conductive n-type semiconductor layer 414 is at least partly absent from between the p-type semiconductor portion 448 and the substrate 412. The p-type semiconductor portion 448 is in the first portion 418 of the part of the PIC. The n-type semiconductor portion 446 is in the second portion 320 of the part of the PIC. An electrical conductivity of the first portion 418 of the part of the PIC is less than an electrical conductivity of the second portion 420 of the part of the PIC at least partly because the n-type semiconductor portion 446 has a greater electrical conductivity than the p-type semiconductor portion 448.

The p-type semiconductor portion 448 is entirely within the first portion 418 of the part of the PIC and the n-type semiconductor portion 446 is entirely within the second portion 420 of the part of the PIC. In other examples the p-type semiconductor portion is partly in the first portion 418 of the part of the PIC; and the n-type semiconductor portion 446 is partly in the second portion 420 of the part of the PIC.

The electrical conductivity of the semiconductor waveguide is reduced compared to other semiconductor waveguides. The reduced electrically conductivity of the semiconductor waveguide was found to reduce or prevent electrical current flowing between components of the PIC and the photodiode through the semiconductor waveguide.

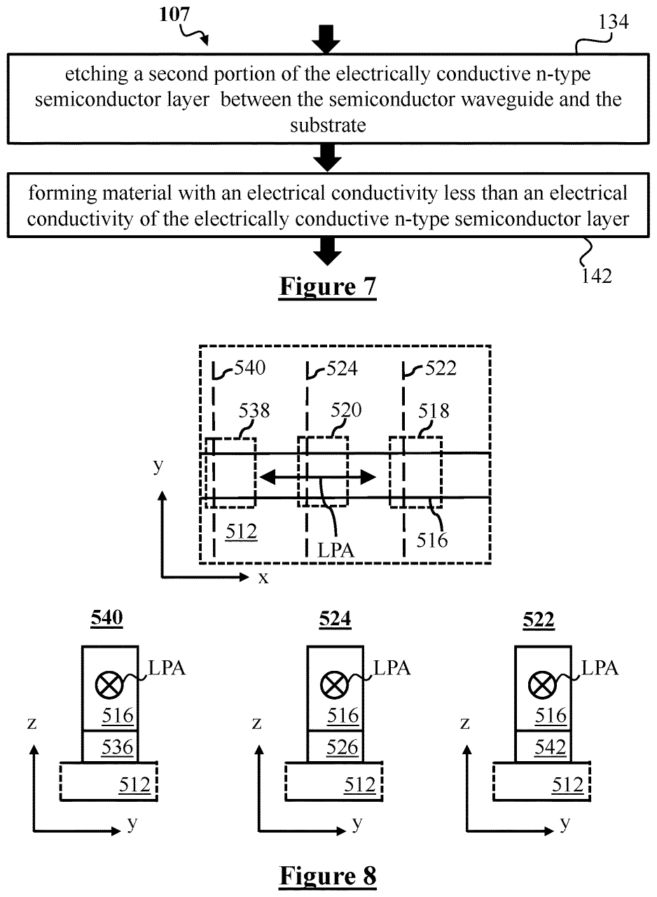

A description of a method 107 of further examples is now given in relation to FIG. 7 and FIG. 8. The method 107 of FIGS. 7 and 8 is an additional part of the method 101 previously described in relation to FIG. 1 and FIG. 2 and can be added to the method 101 of FIG. 1 and FIG. 2 at any point after forming 104 the semiconductor waveguide.

FIG. 7 is a flow diagram of the method 107 in accordance with further examples. FIG. 8 shows schematically views of the part of the PIC of FIG. 7. The side cross-sections of FIG. 8 are taken perpendicular to the light propagation axis LPA, and are on a first plane 522, a second plane 524, and a third plane 540 respectively, and are indicated with the reference numeral of the plane they are taken on in the Figure. The first plane 522, second plane 524 and third plane 540 are though the first portion 518 of the part of the PIC, a second portion 520 of the part of the PIC, and a third portion 540 of the part of the PIC respectively. The relative orientations of each view are indicated using cartesian x-, y-, and z-axes.

Where a feature in relation to FIG. 8 corresponds with a feature described using FIG. 2, a reference numeral is used which is 300 greater than the corresponding reference numeral used for FIG. 2 (e.g., 212 in FIG. 2 is 512 in FIG. 8); corresponding descriptions for such features apply here also.

The method 107 comprises etching 134 a second portion of the electrically conductive n-type semiconductor layer between the semiconductor waveguide 516 and the substrate 512. The second portion of the electrically conductive n-type semiconductor layer is in a third portion 538 of the part of the PIC. The second portion 520 of the part of the PIC is between the first portion 518 of the part of the PIC and the third portion 538 of the part of the PIC. In other examples, the second portion of the part of the PIC is not between the first portion of the part of the PIC and the third portion of the part of the PIC.

The method 107 then comprises forming 142 material 536 and 542 with an electrical conductivity less than an electrical conductivity of the electrically conductive n-type semiconductor layer. The material 536 is in place of the portion of the electrically conductive n-type semiconductor layer and the material 542 in place of the of the second portion of the electrically conductive n-type semiconductor layer. The material is an electrical insulator. In other examples the material is at least one of a dielectric, a gas, or a polymer. In other examples the method does not comprise forming the material.

An electrical conductivity of the second portion 520 of the part of the PIC is more than each of: an electrical conductivity of the first portion 518 of the part of the PIC and an electrical conductivity of the third portion 538 of the part of the PIC. This is at least partly because the n-type semiconductor portion 526 has a greater electrical conductivity than the material 542 and 536.

The material 542 and 536 is entirely within the first portion 518 of the part of the PIC and the third portion 538 of the part of the PIC. The electrically conductive n-type semiconductor layer is partly within the second portion 520 of the part of the PIC. In other examples the material is at least partly within the first portion 518 of the part of the PIC, and the third portion 538 of the part of the PIC.

In some such examples, the material reduces or prevents electrical current flowing between components of the PIC and the photodiode through the electrically conductive n-type semiconductor layer. This was found to reduce or prevent electrical current flowing between components of the PIC and the photodiode.

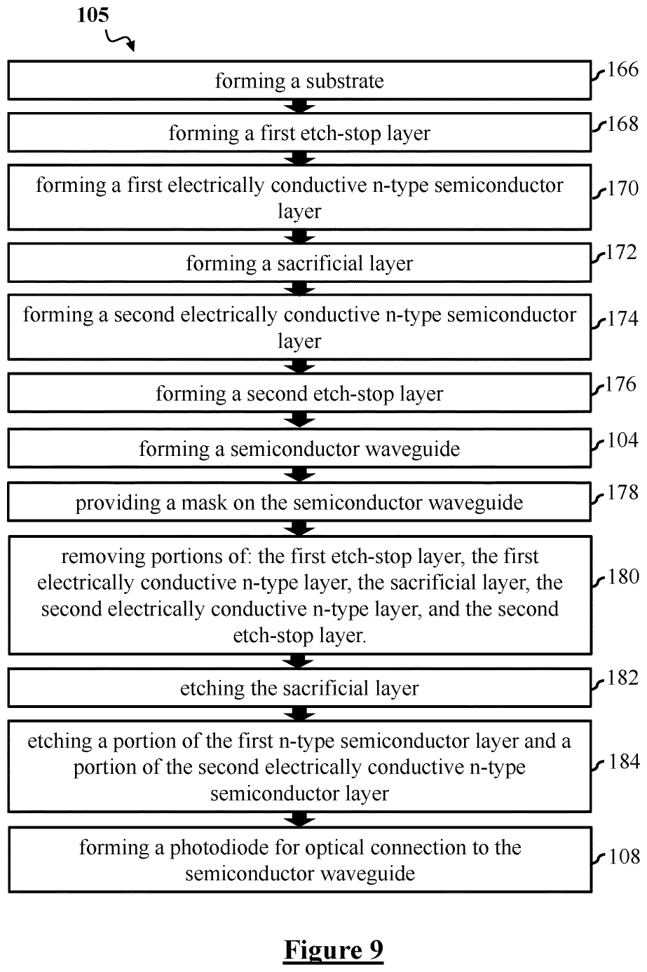

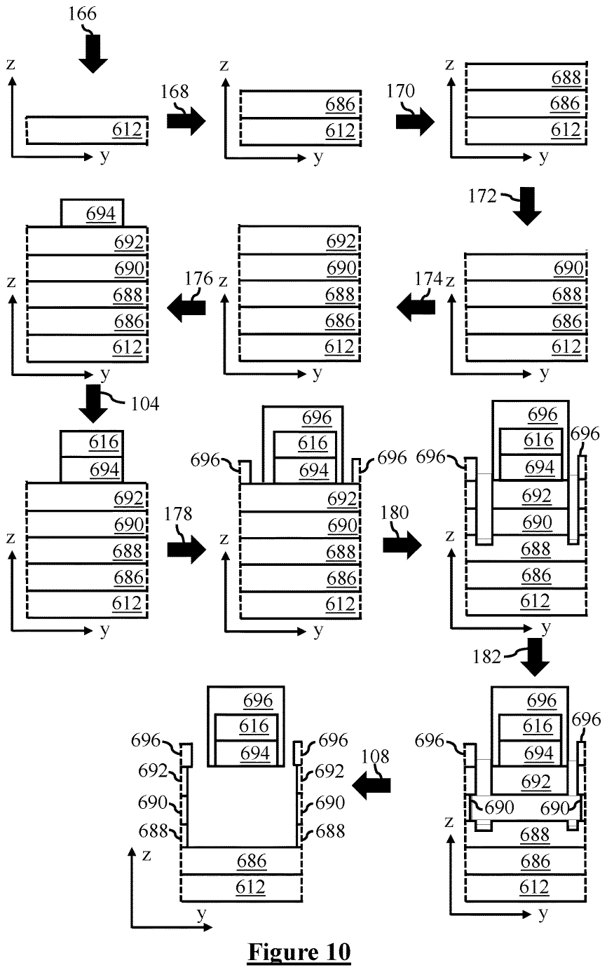

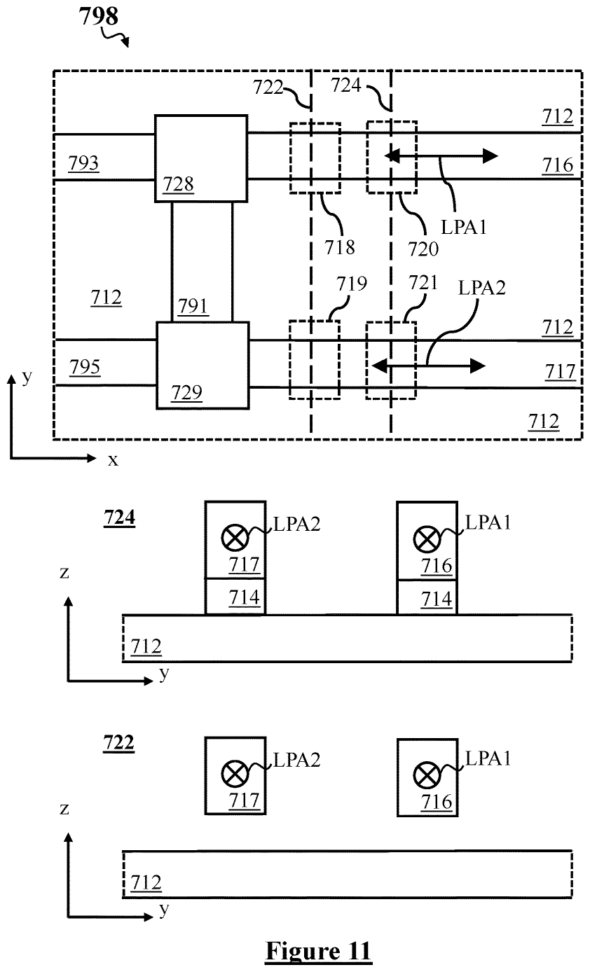

A description of a method of manufacturing part of a PIC of further examples herein is now given with reference to FIG. 9 and FIG. 10.

FIG. 9 is a flow diagram of the method 105 of manufacturing a part of a PIC. FIG. 10 shows schematically a flow diagram of side cross-sections of the part of the PIC during the method 105. The relative orientations of each view are indicated using cartesian x-, y-, and z-axes.

Where a feature in relation to FIG. 10 corresponds with a feature described using any of FIG. 2, a reference numeral is used which is 400 greater than the corresponding reference numeral used for FIG. 2 (e.g., 216 in FIG. 2 is 616 in FIG. 10); corresponding descriptions for such features apply here also.

The method 105 comprises forming 166 a substrate 612. In some examples the substrate comprises a plurality of layers. The method 105 then comprises forming 168 a first etch-stop layer 686. The first etch-stop layer 686 is on the substrate 612 and in contact with the substrate. In other examples the first etch-stop layer is not in contact with the substrate.

In the examples of FIGS. 24 to 35 the electrically conductive n-type semiconductor layer comprises a first electrically conductive semiconductor layer 688 and a second electrically conductive n-type semiconductor layer 692. In other examples, the electrically conductive n-type semiconductor layer comprises different layers, for example more than two layers. The method 105 comprises forming 170 the first electrically conductive n-type semiconductor layer 688 on the first etch-stop layer 686. The first electrically conductive n-type semiconductor layer 688 is in contact with the first etch-stop layer 686. In other examples the first electrically conductive n-type semiconductor layer is not contact with the first etch-stop layer. The first electrically conductive n-type semiconductor layer 688 and the second electrically conductive n-type semiconductor layer 692 are formed of the same material. In other examples, the first electrically conductive n-type semiconductor layer and the second electrically conductive n-type semiconductor layer are not formed of the same material.

Next, the method 105 comprises forming 172 a sacrificial layer 690 on the first electrically conductive n-type semiconductor layer 688. The sacrificial layer 690 is in contact with a portion of the first electrically conductive n-type semiconductor layer 688. The sacrificial layer 690 is less resistant to an etchant than the electrically conductive n-type semiconductor layer, the first electrically conductive n-type semiconductor layer 688, and the second electrically conductive n-type semiconductor layer 692. The etchant is later used for etching 182 the sacrificial layer 690.

The method 105 then comprises forming 174 the second electrically conductive n-type semiconductor layer 692 on the sacrificial layer 690. The second electrically conductive n-type semiconductor layer 692 is in contact with the sacrificial layer 690.

The method 105 then comprises forming 176 a second etch-stop layer 694 on the second electrically conductive n-type semiconductor layer 692. The first etch-stop layer 686 and the second etch-stop layer 694 are each more resistant to an etchant used for the later etching 184 the portion of the first n-type semiconductor layer 688 and the portion of the second electrically conductive n-type semiconductor layer 692.

Next, the method 105 comprises forming 104 a semiconductor waveguide 616 on the second etch-stop layer 694. The waveguide 616 is in contact with the second etch-stop layer 694. The first etch-stop layer 686 is formed of the same material as the second etch-stop layer 694. The first etch-stop layer 686 and the second etch-stop layer comprise indium gallium arsenide phosphide (InGaAsP). In other examples, at least one of: the first etch-stop layer and the second etch-stop layer do not comprise InGaAsP; or the first etch-stop layer is formed of a different material to the second etch stop layer.

After forming 104 the semiconductor waveguide, the first n-type semiconductor layer and the second electrically conductive n-type semiconductor layer: the first etch-stop layer is between the substrate and the electrically conductive n-type semiconductor layer.

After forming 104 the semiconductor waveguide: the second etch stop-layer 694 is between the semiconductor waveguide and the electrically conductive n-type semiconductor layer.

The method 105 then comprises forming 178 a mask 696 on the semiconductor waveguide 616. The mask 696 is an etch mask; in other examples, the mask is a lithography mask or other mask. The mask is not for preventing etching of the second electrically conductive n-type semiconductor layer 692 and is for preventing the etching of the semiconductor waveguide 616. The methods of other examples do not comprise forming a mask, or the mask is formed at a different point in the method.

Next, the method comprises removing 180 portions of: the first etch-stop layer 686, the first electrically conductive n-type layer 688, the sacrificial layer 690, the second electrically conductive n-type layer 692, and the second etch-stop layer 694. The removal comprises forming a lithography mask, lithography, and removal of the lithography mask; other processes of removal are envisaged. The first electrically conductive n-type layer 688 is used a lithography buffer and the first etch stop layer 686 is not removed.

The method 105 then comprises etching 182 the sacrificial layer 690. The etching 182 of the sacrificial layer 690 is an under-etch.

Next, the method 105 comprises etching 184 a portion of the first electrically conductive n-type semiconductor layer and a portion of the second electrically conductive n-type semiconductor layer. The portion of the first n-type semiconductor layer and a portion of the second electrically conductive n-type semiconductor layer are both between the semiconductor waveguide 616 and the substrate 612. The etching 184 of the portions of the first and second electrically conductive n-type semiconductor layers is without etching the semiconductor waveguide 616. The first etch stop layer 686 prevents etching of the substrate 612. The second etch stop layer 694 prevents etching of the semiconductor waveguide 616.

In other examples, the method then comprises at least one of: removing the mask or forming an electrical insulator between the first etch mask and the second etch mask.

Similarly to the method of FIG. 1 and FIG. 2, the method 105 of FIG. 9 and FIG. 10 then comprises forming 108 a photodiode for optical connection to the semiconductor waveguide 616. The photodiode is optically connected to the semiconductor waveguide 616.

In some such examples, the electrical current flowing between components of the PIC and the photodiode is reduced or prevented.

A description of further examples herein relating to a balanced photodetector of a PIC is now given with reference to FIG. 11.

FIG. 11 shows schematically a top plan view and side cross-sections of a balanced photodetector 798 of a PIC of examples. The side cross-sections are taken perpendicular to the light propagation axis LPA1 of the first semiconductor waveguide 716 and the light propagation axis LPA2 of the second semiconductor waveguide 717 respectively, and on a first plane 722 and a second plane 724 respectively, and are indicated as such. The relative orientations of each view are indicated using cartesian x-, y-, and z-axes.

Where a feature in relation to FIG. 11 corresponds with a feature described using any of FIG. 2, a reference numeral is used which is 500 greater than the corresponding reference numeral used for FIG. 2 (e.g., 216 in FIG. 2 is 716 in FIG. 11); corresponding descriptions for such features apply here also.

The balanced photodetector 798 comprises a first semiconductor waveguide 716; a second semiconductor waveguide 717; and an electrically conductive n-type semiconductor layer 714 on the substrate 712. The electrically conductive n-type semiconductor layer 714 is not between the first semiconductor waveguide 716 and the substrate 712 in a first portion 718 of the balanced photodetector 798. A portion of the electrically conductive n-type semiconductor layer 714 in the first portion 718 of the balanced photodetector 798 having been removed by etching between the first semiconductor waveguide 716 and the substrate 712. The electrically conductive n-type semiconductor layer 714 is between the first semiconductor waveguide 716 and the substrate 712 in a second portion 720 of the balanced photodetector 798. The electrically conductive n-type semiconductor layer 714 is not between the second semiconductor waveguide 717 and the substrate 712 in a third portion 719 of the balanced photodetector 798. A portion of the electrically conductive n-type semiconductor layer 714 in the third portion 719 of the balanced photodetector 798 having been removed by etching between the first semiconductor waveguide 716 and the substrate 712. The electrically conductive n-type semiconductor layer 714 is between the second semiconductor waveguide 716 and the substrate 712 in a second portion 721 of the balanced photodetector 798.

The balanced photodetector 798 comprises a first photodiode 728 optically connected to the first semiconductor waveguide 716, and a second photodiode 729 optically connected to the first semiconductor waveguide 717. The first photodiode 716 comprises the same materials as the second photodiode 717. In other examples, the first photodiode 716 and the second photodiode 717 are of different materials.

The balanced photodetector 798 comprises a first electrode 791, a second electrode 793, and a third electrode 795. The first electrode is electrically connected to the first photodiode 728 and the second photodiode 729. The first electrode 791 is electrically connected to the p-type semiconductor of the first photodiode 728 and the n-type semiconductor of the second photodiode 729. The second electrode 793 is electrically connected to the n-type semiconductor of the first photodiode 728. The third electrode is electrically connected to the p-type semiconductor of the second photodiode 729. In other examples: the first electrode is electrically connected to the n-type semiconductor of the first photodiode and the p-type semiconductor of the second photodiode; the second electrode is electrically connected to the p-type semiconductor of the first photodiode; and the third electrode is electrically connected to the n-type semiconductor of the second photodiode.

The balanced photodetector 798 is configurable to measure a difference between light guided by the first semiconductor waveguide 716 and light guided by the second semiconductor waveguide 717. When in use, an electrical current between the second electrode 793 and the third electrode 795 is related to a difference between light guided by the first semiconductor waveguide 716 and light guided by the second semiconductor waveguide 717. The difference between light guided by the first semiconductor waveguide and light guided by the second semiconductor waveguide is, for example, a difference between respective values of a property of the respective light guided by the first and second semiconductor waveguides. The property of the respective light guided by the first and second semiconductor waveguides is, for example, at least one of: intensity, irradiance, amplitude, photon count, wavelength, or polarisation. Other properties are envisaged. In some examples, the balanced photodetector 798 is for at least one of: interferometry, light detection and ranging (LiDAR), frequency-modulated continuous wave light detection and ranging (FMCW LiDAR), coherent detection, telecommunications, or quantum computing. Other uses of the balanced photodiode are envisaged.

In some such examples, there is little or no electrical current flowing between the first photodiode and the second photodiode through the electrically conductive n-type semiconductor layer, the first waveguide or the second waveguide. This increases the lifetime of PIC and the balanced photodiode, reduces the error induced in the balanced photodiode, allows more sensitive detection, and allows more efficient photodetection.

A method of manufacturing the balanced photodetector 798 of FIG. 11 comprises any of the methods described herein, for example the method 101 of FIG. 1, and additionally: forming the second semiconductor waveguide 717 on the electrically conductive n-type semiconductor layer; forming a second photodiode 729 for optical connection to the second semiconductor waveguide 717; and forming the first electrode 791 for electrical connection to the first photodetector 728 and the second photodetector 729.

Some examples herein relate to a PIC comprising the part of a PIC described above. In some examples the PIC is for at least one of: interferometry, light detection and ranging (LiDAR), frequency-modulated continuous wave light detection and ranging (FMCW LiDAR), coherent detection, telecommunications, or quantum computing. Other uses of the PIC are envisaged.

A description of some terms and features used previously is now given, to elaborate on features of examples described herein.

In some examples herein forming comprises a manufacture process, e.g., using known techniques such as: epitaxy, metalorganic vapour-phase epitaxy (MOVPE), surface passivation, lithography, photolithography, ion implantation, etching, dry etching ion etching, wet etching, buffered oxide etching, plasma ashing, plasma etching, thermal treatment, annealing, thermal oxidation, chemical vapor deposition, atomic layer deposition, physical vapor deposition, molecular beam epitaxy, laser lift-off, electrochemical deposition, electroplating, chemical-mechanical polishing, wafer fusion, anodic bonding, or adhesion.

Dashed lines in the Figures herein (for example indicating the substrate 212 and the electrically conductive n-type semiconductor layer 214 in FIG. 2) that are not labelled with a figure numeral (for example, first plane 222 is labelled with a figure numeral) are used to indicate where the feature may extend laterally beyond the illustration (for example, as to other parts of the PIC).

Etching referred to herein is the use of an etchant to remove material, for example, by dissolving or vaporising the material in the etchant. The etchant is chosen depending on the material being etched and any material that is not to be etched as different materials will bet etched at a different rate. If a first material is more resistant to an etchant than a second material, in the same conditions (such temperature or pressure) the first material will be etched at a slower rate than the second material, e.g. fewer units of mass or volume of the first material will be dissolved or vaporised into the etchant per unit time than the second material. Etching herein comprises at least one of wet etching or dry etching. In some examples, etching comprises at least one of: isotropic etching, anisotropic etching, or under-etching. In some examples, a mask which is highly resistant to an etchant is used to prevent etching by the etchant of a first portion of the part of the PIC and allow etching by the etchant of a second portion of the part of the PIC. In some examples, etching comprises forming a mask over a first portion of the part of the PIC, etching a second portion of the part of the PIC, and removing the mask.

In wet etching herein a liquid-phase etchant is used to dissolve material. Example liquid-phase etchants include hydrochloric acid (HCl), hydrofluoric acid (HF), phosphoric acid (H₃PO₄), acetic acid (CH₃COOH), citric acid (C₆H₈O₇), nitric acid (HNO₃₎, ethylenediamine pyrocatechol (EDP), potassium hydroxide (KOH), isopropyl alcohol (IPA), tetramethylammonium hydroxide (TMAH), hydrogen peroxide (H₂O₂), water (H₂O), and mixtures thereof. Other liquid-phase etchants are envisaged. In some examples, a mixture of HCL, H₃PO₄ and H₂O is used, which etches the desired material. In some examples, etchants for wet etching include a catalyst such metal particles.

In dry etching herein a plasma-phase etchant is used to dissolve material. In some examples, dry etching is plasma etching. Example plasma-phase etchants include iron chloride (FeCl₃), tetrafluoromethane (CF₄), sulfur hexafluoride (SF₆), nitrogen trifluoride (NF₃), fluoroform (CHF₃), tetrachloromethane (CCl₄), silicon tetrachloride (SiCl₄), boron trichloride (BCl₃), dichlorodifluoromethane (CCl₂F₂), chlorine Cl₂, or mixes thereof.

Isotropic etching herein is when the material being etched is etched at the same rate (or has the same resistance to the etchant) independent of the orientation of the material. Anisotropic etching herein is when the material being etched is etched at a different rate (or has a different resistance to the etchant) dependent of the orientation of the material, such as because of the crystal planes of the material.

Under-etching herein is when a first material between a second material and a third material (in some examples, the third material is the same as the second material).

An electrical conductor herein comprises an electrically conductive material. In some examples the electrical conductor comprises an electrically conductive structure. In some examples, the electrical conductivity of the electrical conductor does not reduce or prevent electrical crosstalk and/or significant conductance of ions and/or electrons across the electrical conductor.

A semiconductor herein is a material with a Fermi level within an electronic bandgap between its electronic valance and conduction bands. An energy of the electronic bandgap is low enough for the conduction band to be thermally populated by electrons or electron holes, for example at 298 Kelvin (K). An electrical conductivity of a semiconductor increases with temperature. An n-type semiconductor herein is a semiconductor that has been doped with an electron donor. Example electron donors for n-type semiconductors herein include iron (Fe), boron (B), phosphorous (P), arsenic (As), antimony (Sb), bismuth (Bi), Lithium (Li), tellurium (Te), or sulfur (S). Other electron doners are envisaged. A p-type semiconductor herein is a semiconductor that has been doped with an electron hole donor. Example electron hole donors include zinc (Zn), germanium (Ge), silicon (Si), nitrogen (N), beryllium (Be), chromium (Cr), magnesium (Mg), or tin (Sn). Other electron hole doners are envisaged.

An electrically conductive n-type semiconductor referred to herein is a n-type semiconductor that is also an electrical conductor, for example, iron doped indium phosphide (Fe—InP). Other electrically conductive n-type semiconductors are envisaged. In some examples, the electrical-conductivity of the electrically conductive n-type semiconductor layer herein at 20 Celsius (293 Kelvin) is more than at least one of 0.1 Siemens per metre, 1 Siemens per metre, 10 Siemens per metre, 100 Siemens per metre, 1000 Siemens per metre, 10000 Siemens per metre, or 100000 Siemens per metre. A Siemens per metre (S/m) is equal to an Ampere squared second cubed per kilogram per metre cubed (kg⁻¹·m⁻³·s³·A²). In some examples, the electrical resistivity of the electrically conductive n-type semiconductor layer herein at 20 Celsius (293 Kelvin) is less than at least one of 0.00001 Ohm metres, 0.0001 Ohm metres, 0.001 Ohm metres, 0.01 Ohm metres, 0.1 Ohm metres, 1 Ohm metres, or 10 Ohm metres. An Ohm metre (Ω·m) is equal to a kilogram metre cubed per Ampere squared per second cubed (kg·m³·s⁻³·A⁻²).

In some examples, the electrically conductive n-type semiconductor layer is common to, or shared by: the photodiode, at least part of the waveguide, and at least one other component of the PIC. In some examples, the electrically conductive n-type semiconductor layer is a common electrical earth. In some examples, the electrically conductive n-type semiconductor layer being a common electrical earth simplifies manufacture of the PIC, as the same layer can be used by multiple components, which facilitates incorporation of the photodiode and the waveguide into a generic photonic platform for a PIC.

A semiconductor waveguide herein is for guiding light; when a semiconductor waveguide is in use light propagates along the semiconductor waveguide. A semiconductor waveguide comprises a core and cladding at least partly in contact with the core. Properties of a semiconductor waveguide including, for example: a boundary of the semiconductor waveguide, a boundary between the core and the cladding, the refractive index of the core, the refractive index of the cladding, and/or the structure of the semiconductor waveguide at least partly confine light propagating along the waveguide to within the semiconductor waveguide. For example, light propagating along the semiconductor waveguide might be predominantly within the core. In some examples, the boundary between the core and the cladding can be thought of as resulting in constructive interference of light which confines light to propagate substantially within the core. An evanescent field may exist in the cladding when light is guided by the semiconductor waveguide. The cladding may comprise a solid structure; however, in some examples the cladding comprises gas, liquid and/or a vacuum in contact with the core. The core may have a greater refractive index than the cladding for the wavelengths of light guided by the semiconductor waveguide. In some examples, the cladding comprises a plurality of portions, e.g., with different refractive indices. Examples of such cladding include step-index cladding and graded-index cladding. In some examples the semiconductor waveguide comprises a plurality of cores; such semiconductor waveguides may be referred to as multi-core semiconductor waveguides. In some examples, the semiconductor waveguide is at least one of: a ridge semiconductor waveguide, a semiconductor junction or an electro-refractive modulator.

An electro-refractive modulator is tunable by an electro-refractive effect such as the Pockels effect or the Kerr effect, with the refractive index of a material dependent on the electric field applied to it. In some examples, the electro-refractive modulator is a diode and/or is reversed biased. Consequently, an electro-refractive modulator requires a material that presents an electro-optic effect such as indium phosphide (InP), indium gallium arsenide phosphide (InGaAsP), aluminium gallium arsenide (AlGaAs), lithium niobate (LiNbO3), or beta barium borate (BBO).

A photodiode herein is a semiconductor diode that produces an electrical current when it absorbs photons. In some examples, the photodiode comprises an n-type semiconductor portion, and a p-type semiconductor portion. In some such examples the photodiode further comprises an intrinsic semiconductor portion between the n-type semiconductor portion and the p-type semiconductor portion. In some examples, the photodiode is at least one of: a photovoltaic, a photoconductive, a phototransistor, an avalanche photodiode or a solaristor. In some examples the photodiode comprises at least one of: silicon (Si), germanium (Ge), indium gallium arsenide (InGaAs), lead sulfide (PbS), or mercury cadmium telluride (HgCdTe).

A photodetector herein is a device that produces an electrical current or an electrical voltage relating to an amplitude or intensity of photons incident on a detection surface of the photodetector or a photodiode.

A balanced photodetector is a device that produces an electrical current or an electrical voltage relating to a difference between photons incident on first and second detection surfaces of the balanced photodetector or a first photodiode and a second photodiode.

An optical connection is such that light propagates between the optically connected elements. The optically connected optical elements are, for example, configured such that light may propagate through free space between the optically connected optical elements and/or the optically connected optical elements are connected by a waveguide such that light may propagate through the waveguide between the optically connected optical elements. As the skilled person will appreciate, optical as used herein refers to at least one of ultraviolet, visible, mid-infrared, infrared C-band, or infrared light.

A PIC herein integrates a plurality of photonic functions, for example any of a semiconductor optical amplifier, an electro-optical modulator, an interferometer, a Mach-Zehnder interferometer, a grating, a laser or a photodiode, though other photonic functions are envisaged. In some examples, a PIC is configured for use with at least one of ultraviolet light, visible light, or infrared light. Optical radiation e.g. includes at least one of ultraviolet light, visible light, or infrared light. In some examples, a PIC comprises an electrical circuit. PICs may be used for communications devices, biomedical devices, and photonic computing, but other applications are envisaged.

A component of a PIC can be considered a structure, building block or assembly designed to perform a particular optical and/or electrical function in the PIC, such as coupling, waveguiding, amplification, modulation, interfere or another optical function. A component can be electrically active or electrically passive depending, e.g., on whether the component comprises electrodes for application of a voltage and/or electrical current for the component to perform the optical function.

An electrical insulator herein comprises an electrically-insulative material. In some examples, the electrical insulator comprises an electrically-insulative structure. In some examples, an electrical insulator comprises a semiconductor and/or a dielectric. In some examples, an electrical conductivity of an electrical insulator herein at 20 Celsius (293 Kelvin) is less than at least one of 0.00001 Siemens per metre, 0.0001 Siemens per metre, 0.001 Siemens per metre, 0.01 Siemens per metre, 0.1 Siemens per metre, 1 Siemens per metre, or 10 Siemens per metre. In some examples, an electrical resistivity of an electrical insulator herein at 20 Celsius (293 Kelvin) is more than at least one of 0.1 Ohm metres, 1 Ohm metres, 10 Ohm metres, 100 Ohm metres, 1000 Ohm metres, 10000 Ohm metres, or 100000 Ohm metres.

In some examples, the electrical resistance between the photodiode and other components of the PIC or between the first photodiode and the second photodiode is more than at least one of: 0.1 Megaohms, 1 Megaohm, 10 Megaohms, or 100 Megaohms.

In some examples, a thickness of at least of one of: the semiconductor layer, the p-type semiconductor portion, or the n-type semiconductor portion is less than at least one of: 1 micrometre, 600 nanometres, 550 nanometres, 500 nanometres, or 200 nanometres. The thickness is perpendicular to the light propagation axis.

A substrate may also be referred to as a chip, a slice, a wafer, or a layer. A substrate is, e.g., a generally planar or relatively thin portion of material, and in some examples is crystalline. A substrate may be a disc or part of a disc of crystalline Si for use in a semiconductor fabrication plant, and in some such examples is a 125 gram, 300 millimetre diameter disc. A substrate may alternatively be a disc or part of a disc of crystalline InP for use in a semiconductor fabrication plant, and in some such examples is a 25 millimetre, 51 millimetre, 76 millimetre, 100 millimetre, 200 millimetre or 300 millimetre diameter disc. A substrate referred to herein is, for example, a single layer of the same homogenous material, though it is envisaged for other examples that a substrate instead comprises one or more layers or portions each deposited or formed independently of each other (for example one after another during a manufacture process to form a stack of sub-layers which together could be considered a substrate). In some examples, a substrate comprises portions of different materials, for example, for fabrication.

In some examples, the substrate herein is a semiconductor, a III-V semiconductor, a polymer, and/or a dielectric. In some examples, the substrate comprises at least one of: silicon (Si), gallium (Ga), germanium (Gr), lithium niobate (LiNbO₃), graphene (C), indium (In), or an alloy, oxide, nitride, or phosphide of at least one of such. In some examples, the substrate comprises an electrical-insulator. In some examples, an electrical conductivity of the substrate at 20 Celsius (293 Kelvin) is less than at least one of 0.00001 Siemens per metre, 0.0001 Siemens per metre, 0.001 Siemens per metre, 0.01 Siemens per metre, 0.1 Siemens per metre, 1 Siemens per metre, or 10 Siemens per metre. In some examples, an electrical resistivity of the substrate at 20 Celsius (293 Kelvin) is more than at least one of 0.1 Ohm metres, 1 Ohm metres, 10 Ohm metres, 100 Ohm metres, 1000 Ohm metres, 10000 Ohm metres, or 100000 Ohm metres.

In some examples, the layer or portion herein is a single layer of the same homogenous material, though it is envisaged for other examples that a layer instead comprises one or more sub-layers or portions each deposited or formed independently of each other (e.g., one after another during a fabrication process to form a stack of sub-layers which together could be considered a layer). A layer or portion may have sub-portions of different materials, for example, for fabrication. Sub-portions of a layer or portion may have different dopant concentrations.

In some examples at least one of: the semiconductor waveguide, the intrinsic semiconductor layer, the first semiconductor waveguide, the second semiconductor waveguide, the photodiode, the first photodiode, or the second photodiode comprises indium gallium arsenide phosphide (InGaAsP).

In some examples, any of the portions, layers, materials, or electrodes described herein, comprises at least one of a semiconductor, a dielectric, or a polymer.

In various examples, a semiconductor described herein, comprises at least one of Si, InP, gallium arsenide (GaAs), gallium antimonide (GaSb), gallium nitride (GaN), indium gallium arsenide (InGaAs), indium gallium arsenide phosphide (InGaAsP), indium aluminium arsenide (InAlAs), indium aluminium gallium arsenide (InAlGaAs), AlGaAs, InGaAsP, SiN, silicon oxide (SiO2), tantalum pentoxide (Ta2O5 or tantala), aluminium oxide (Al2O3, or alumina), aluminium nitride (AlN) or lithium niobate (LiNbO3). Other materials are envisaged in further examples.

It is to be understood that any feature described in relation to any one example may be used alone, or in combination with other features described, and may also be used in combination with one or more features of any other of the example, or any combination of any other of the examples. Furthermore, equivalents and modifications not described above may also be employed without departing from the scope of the accompanying claims.

1. A method of manufacturing part of a photonic integrated circuit, the method comprising:
(i) forming an electrically conductive n-type semiconductor layer on a substrate;
(ii) forming a semiconductor waveguide on the electrically conductive n-type semiconductor layer;
(iii) etching a portion of the electrically conductive n-type semiconductor layer between the semiconductor waveguide and the substrate, without etching a portion of the semiconductor waveguide on the portion of the electrically conductive n-type semiconductor layer; and
forming a photodiode for optical connection to the semiconductor waveguide.

2. The method of claim 1, comprising:
after (iii) and in place of the portion of the electrically conductive n-type semiconductor layer etched in (iii), forming material with an electrical conductivity less than an electrical conductivity of the electrically conductive n-type semiconductor layer.

3. The method of claim 1, wherein (ii) comprises:
forming a semiconductor layer on the electrically conductive n-type semiconductor layer;
forming an intrinsic semiconductor layer on the semiconductor layer; and
forming a p-type semiconductor layer on the intrinsic semiconductor layer,
the intrinsic semiconductor layer between the semiconductor layer and the p-type semiconductor layer, the semiconductor layer between the intrinsic semiconductor layer and the electrically conductive n-type semiconductor layer.

4. The method of claim 3, wherein forming the semiconductor layer comprises:
doping a portion of the semiconductor layer of the semiconductor waveguide to form:
an n-type semiconductor portion of the semiconductor layer; and
a p-type semiconductor portion of the semiconductor layer, an electrical conductivity of the p-type semiconductor portion less than an electrical conductivity of the n-type semiconductor portion, and after (iii) the electrically conductive n-type semiconductor layer is at least partly absent from between the p-type semiconductor portion and the substrate.

5. The method of claim 4, wherein a zinc ion is a dopant used in doping the portion of the semiconductor layer.

6. The method of claim 3, wherein forming the semiconductor layer comprises:
forming an n-type semiconductor portion on a first surface of the electrically conductive n-type semiconductor layer; and
forming a p-type semiconductor portion on a second surface of the electrically conductive n-type semiconductor layer, an electrical conductivity of the p-type semiconductor portion less than an electrical conductivity of the n-type semiconductor portion, and after (iii) the electrically conductive n-type semiconductor layer is at least partly absent from between the p-type semiconductor portion and the substrate.

7. The method of claim 1, comprising:
forming a first etch-stop layer on the substrate, and after (ii) the first etch-stop layer is between the substrate and the electrically conductive n-type semiconductor layer; and
forming a second etch-stop layer on the electrically conductive n-type semiconductor layer, and after (ii) the second etch stop-layer is between the electrically conductive n-type semiconductor layer and the semiconductor waveguide,
the first etch-stop layer and the second etch-stop layer each more resistant to an etchant used for the etching the portion of the electrically conductive n-type semiconductor layer than the electrically conductive n-type semiconductor layer.

8. The method of claim 7, comprising:
forming a sacrificial layer, and after (ii) a portion of the sacrificial layer is between the semiconductor waveguide and the substrate and in contact with the portion of the electrically conductive n-type semiconductor layer, the sacrificial layer less resistant to the etchant than the electrically conductive n-type semiconductor layer; and
after (ii) and before (iii), etching the portion of the sacrificial layer.

9. The method of claim 1, wherein the portion of the electrically conductive n-type semiconductor layer between the semiconductor waveguide and the substrate is a first portion of the electrically conductive n-type semiconductor layer between the semiconductor waveguide and the substrate, the portion of the semiconductor waveguide is a first portion of the semiconductor waveguide, and the method comprises:
etching a second portion of the electrically conductive n-type semiconductor layer between the semiconductor waveguide and the substrate without etching a second portion of the semiconductor waveguide on the second portion of the electrically conductive n-type semiconductor layer.

10. The method of claim 1, wherein the semiconductor waveguide is a first semiconductor waveguide, the photodiode is a first photodiode, and the method comprises:
forming a second semiconductor waveguide on the electrically conductive n-type semiconductor layer;
forming a second photodiode for optical connection to the second semiconductor waveguide;
forming an electrode for electrical connection to the first photodetector and the second photodetector.

11. The method of claim 10, comprising:
etching a portion of the electrically conductive n-type semiconductor layer between the second semiconductor waveguide and the substrate without etching a portion of the second semiconductor waveguide on the portion of the electrically conductive n-type semiconductor layer between the second semiconductor waveguide and the substrate.

12. The part of a photonic integrated circuit obtained by claim 1.

13. A part of a photonic integrated circuit comprising:
a semiconductor waveguide on a substrate;
an electrically conductive n-type semiconductor layer between the semiconductor waveguide and the substrate, a portion of the electrically conductive n-type semiconductor layer having been removed by etching between the semiconductor waveguide and the substrate; and
a photodiode optically connected to the semiconductor waveguide.

14. The part of claim 13, a material with an electrical conductivity less than an electrical conductivity of the electrically conductive n-type semiconductor layer in place of the portion of the electrically conductive n-type semiconductor layer.

15. The part of claim 13 wherein the semiconductor waveguide comprises:
a semiconductor layer comprising
an n-type semiconductor portion on a first surface of the electrically conductive n-type semiconductor layer, and
a p-type semiconductor portion on a second surface of the electrically conductive n-type semiconductor layer, an electrical conductivity of the p-type semiconductor portion less than an electrical conductivity of the n-type semiconductor portion, and the electrically conductive n-type semiconductor layer is at least partly absent from between the p-type semiconductor portion and the substrate;
an intrinsic semiconductor layer on the semiconductor layer; and
a p-type semiconductor layer on the intrinsic semiconductor layer,
the intrinsic semiconductor layer between the semiconductor layer and the p-type semiconductor layer, the semiconductor layer between the intrinsic semiconductor layer and the electrically conductive n-type semiconductor layer.

16. The part of any claim 13, wherein an etchant is used for etching between the semiconductor waveguide and the substrate, and the part comprises:
a first etch-stop layer on the substrate and at least partly between the substrate and the electrically conductive n-type semiconductor layer, and more resistant to the etchant than the electrically conductive n-type semiconductor layer; and
a second etch-stop layer at least partly between the electrically conductive n-type semiconductor layer and the semiconductor waveguide, and more resistant to the etchant than the electrically conductive n-type semiconductor layer.

17. The part of claim 16, comprising a sacrificial layer, a portion of the sacrificial layer:
in contact with the portion of the electrically conductive n-type semiconductor layer having been removed by etching;
between the semiconductor waveguide and the substrate; and
having been removed by etching,
the sacrificial layer less resistant to the etchant than the electrically conductive n-type semiconductor layer.

18. The part of claim 13, wherein:
the portion of the electrically conductive n-type semiconductor layer between the semiconductor waveguide and the substrate is a first portion of the electrically conductive n-type semiconductor layer between the semiconductor waveguide and the substrate;
the portion of the semiconductor waveguide is a first portion of the semiconductor waveguide; and
a second portion of the electrically conductive n-type semiconductor between the semiconductor waveguide and the substrate has been removed by etching without etching a second portion of the semiconductor waveguide on the second portion of the electrically conductive n-type semiconductor layer.

19. The part of claim 13, wherein (i) the semiconductor waveguide is a first semiconductor waveguide, the photodiode is a first photodiode, and the part comprises:
a second semiconductor waveguide on the electrically conductive n-type semiconductor layer;
a second photodiode optically connected to the second semiconductor waveguide;
an electrode electrically connected to the first photodetector and the second photodetector;
or (ii) the semiconductor waveguide is a first semiconductor waveguide, the photodiode is a first photodiode, and the part comprises:
a second semiconductor waveguide on the electrically conductive n-type semiconductor layer;
a second photodiode optically connected to the second semiconductor waveguide;
an electrode electrically connected to the first photodetector and the second photodetector; and
wherein a portion of the electrically conductive n-type semiconductor layer having been removed by etching between the second semiconductor waveguide and the substrate.

20. A photonic integrated circuit comprising:
a semiconductor waveguide on a substrate;
an electrically conductive n-type semiconductor layer between the semiconductor waveguide and the substrate, a portion of the electrically conductive n-type semiconductor layer having been removed by etching between the semiconductor waveguide and the substrate; and
a photodiode optically connected to the semiconductor waveguide.
